(19) United States
(12) Patent Application Publication
(10) Pub. No.: US 2007/0224376 A1
(43) Pub. Date: Sep. 27, 2007

(54) Metallized multi-layer films, methods of manufacture and articles made therefrom

(76) Inventor: Benoit Ambroise, Hachy (BE)

Correspondence Address: EXXONMOBIL CHEMICAL COMPANY, 5200 BAYWAY DRIVE, P.O. BOX 2149, BAYTOWN, TX, 77522-2149, US

(21) Appl. No.: 11/387,178

(22) Filed: Mar. 23, 2006

(51) Int. Cl. B32B 15/085; B32B 15/08; C23C 16/00; B05D 3/00; B05D 7/00; B05D 1/36; H05H 1/00

(52) U.S. Cl. 428/35.9; 428/447; 428/450; 428/461; 428/313.7; 428/339; 428/336; 427/409; 427/419.1; 427/535; 427/294; 427/248.1

(57) ABSTRACT

Multi-layer films particularly suited for packaging applications, including a core layer, a seal layer located on one side of the core layer, the seal layer comprising a polyolefin polymer and a silicone gum and a metallized layer located on the opposite side of the core layer from the seal layer are provided. Optionally, the multi-layer film may have a first tie layer located intermediate the core layer and the seal layer and/or a second tie layer located intermediate the core layer and the metallized layer. Embodiments may have the desirable combination of improved metal adhesion and slip properties.

### FIELD OF THE INVENTION

This invention relates generally to metallized, multi-layer films. More specifically, this invention relates to metallized multi-layer films with improved metal adhesion and slip properties.

### BACKGROUND OF THE INVENTION

In the packaging of certain types of foods including potato chips, snack foods, and the like, it is a common practice to employ a multi-layer film. Polypropylene films are widely used in the packaging industry due to their superior physical properties such as stiffness, moisture barrier characteristics and others. Despite these highly desirable properties, unmodified polypropylene film has the disadvantageous property of having a high inherent coefficient of friction (COF).

As is commonly known in the art, and as used herein, COF is the kinetic film-to-film coefficient of friction used to quantify and compare film frictional surface properties in a consistent and convenient manner. Though a variety of frictional surface contacts exist during film manufacture and processing (i.e., film-to-metal, film-to-chute, film-to-conveyor) film-to-film COF measurements are used for process control to ensure consistent production of a film in a target application.

A high COF makes unmodified polypropylene films difficult to be successfully employed in automatic packaging equipment. Therefore, slip additives are traditionally added to the polymer components of the film to lower the COF and provide improved machinability. Most slip additives used to lower the COF of polypropylene films are migratory, such as fatty amides, erucamide and oleamide. The effectiveness of these additives depends upon their ability to migrate to the surface of the film. The development of the desired low COF value is dependent upon the type and amounts of the slip additives, time and temperature aging effects. The heat history of the film while in storage, during shipping and during subsequent converter processes also affects the COF. Additionally, the presence of fatty amides, erucamide and oleamide types of slip additives results in adverse appearance effects on the film surface manifested by an increase in haze, a decrease in gloss and the presence of streaks. Fatty amides are further undesirable in polymeric materials that are stretched because the elevated temperatures required for stretching results in the emission of fumes around the equipment used for film manufacture. These fumes may be attributed to equipment fouling and production issues such as decreased film quality, film splits and processing downtime necessary to clean the equipment. Fatty amides, erucamide and oleamide types of slip additives also adversely affect the wettability and adhesion of solvent and water-based inks, coatings and adhesives.

Of particular interest to the current invention, the addition of migratory slip agents such as fatty amides, erucamide and oleamide have a potentially negative effect upon adhesion of metal coatings applied to the surface of the film. This negative effect results from the migration of the slip agent through the film (including, typically, the core layer) to the outermost surface of the layer to be metallized.

Improved COF can also be gained by the incorporation of silicone oil into an exterior layer of a multi-layer film. Films containing an appropriate concentration of silicone oil maintain a low COF and perform well on packaging machines. However, immediately upon winding a film with an exterior layer containing silicone oil, a portion of the oil is transferred to the opposite side of the film structure intended for metallization. The presence of silicone oil on the surface of the film intended for metallization contaminates the surface and consequently metallization becomes more difficult.

U.S. Pat. No. 6,773,818 to Cretekos et al. (ExxonMobil Oil Corporation) discloses an oriented multi-layer film containing a core layer and first skin layer, wherein the first skin layer includes a metallocene-catalyzed propylene homopolymer or copolymer, and the first skin layer is metallized. The film may also contain additional layers, such as a second skin layer for heat-sealing, and one or more tie layers. The film may be laminated to other films or non-films. The film exhibits excellent water vapor transmission rates (WVTR) and oxygen transmission rates (OTR).

U.S. Pat. No. 6,824,878 to Migliorini et al (ExxonMobil Oil Corporation) discloses a polymer film comprising a polymeric core layer on the interior of the film; a first transition layer exterior to the core layer, the first transition layer comprising a polyolefin and a silicone additive; and a first skin layer exterior to the first transition layer and the core layer, the skin layer comprising a polyolefin.

U.S. Pat. No. 6,455,150 to Sheppard et al discloses a heat-sealable film comprising: (a) an upper heat-sealable layer comprising (i) an ethylene polymer, copolymer or terpolymer and (ii) a particulate, crosslinked hydrocarbyl-substituted polysiloxane having a mean particle size from about 0.5 μm to about 20.0 μm, as a combined slip agent and antiblock agent; (b) an intermediate core layer comprising a propylene polymer; and (c) a lower heat-sealable layer consisting essentially of (i) an ethylene polymer, copolymer, or terpolymer, (ii) a particulate, crosslinked hydrocarbyl-substituted polysiloxane having a mean particle size of from about 0.5 μm to about 20.0 μm, as a combined slip agent and antiblocking agent; and (iii) from about 0.15 wt % to about 1.5 wt % of a liquid, hydrocarbyl-substituted polysiloxane. The upper heat-sealable layer does not contain a liquid polysiloxane, but may have a coating of liquid polysiloxane transferred from the lower heat-sealable layer.

U.S. Pat. No. 6,495,266 to Migliorini (ExxonMobil Oil Corporation) discloses methods of improving blocking resistant properties and reducing the coefficient of friction of a multilayer film comprising providing at least one layer of an ethylene-propylene impact copolymer having from about 3% to about 30% by weight ethylene, wherein said copolymer has no more than two peaks in the melting curve within the range from about 110° C. to about 165° C., and wherein said layer is non-heat sealable, to a multilayer film having a core layer comprising polypropylene, high density polyethylene (HDPE) or linear low density polyethylene (LLDPE), whereby anti-blocking and coefficient of friction characteristics of said film is improved without the necessity of adding an antiblock or slip agent.

U.S. Pat. No. 6,074,762 to Cretekos et al (Mobil Oil Corporation) discloses a block-resistant film which comprises a core layer of a thermoplastic polymer having a first side and a second side; a functional layer which is printable or sealable or treatable for printing or sealing is on the first side of the core layer, a block-resistant layer is on the second side of the core layer. The block-resistant layer comprises a thermoplastic polymer and an amount of a polydialkylsiloxane, based upon the entire weight of the block-resistant layer, sufficient to inhibit blocking of the block-resistant layer to the functional layer when they are in contact and which polydialkylsiloxane deposits silicon onto the functional layer but the amount of silicon deposited is not substantially detrimental to the printing function or the sealing function.

EP Patent No. 1,353,798 and related Continuation-in-Part U.S. Publication No. 2004-0209070 to Sheppard et al (ExxonMobil Chemical Company) disclose a coextruded, heat-sealable film structure including a core layer of a thermoplastic polymer having a first side and a second side, a functional layer which is printable, sealable, or can be laminated or is treatable for printing, sealing or laminating and is on the first side of the core layer, and a heat-sealable layer on the second side of the core layer. The heat-sealable layer is composed of a thermoplastic polymer and an amount of a slip system, based upon the entire weight of the heat-sealable layer, sufficient to reduce the coefficient of friction and improve the slip performance of the film structure. The slip system is composed of a silicone gum and at least one antiblocking agent. The film structure exhibits the desirable combination of improved converting performance and excellent machinability performance.

None of the films described above combine desired COF reduction and improved metal adhesion for some of today's challenging packaging operations. Opportunities exist for polymer films to replace other packaging substrates, such as paper and foil, for packages requiring superior barrier properties, such as with potato chips and snack packaging. The present invention meets these and other needs.

### SUMMARY OF THE INVENTION

The present invention generally relates to metallized multi-layer films comprising a core layer; a seal layer located on a side of the core layer, the seal layer comprising a polyolefin polymer and a silicone gum, the silicone gum having a viscosity of at least 2 million centistokes at 25° C., wherein the outermost surface of the seal layer has a coefficient of friction less than about 0.4; and a metallized layer located on a side of the core layer opposite the seal layer.

In yet another embodiment, the invention generally relates to a metallized multi-layer film comprising a core layer; a seal layer located on a side of the core layer, the seal layer comprising a polyolefin polymer and a silicone gum, the silicone gum having a viscosity of at least two million centistokes at 25° C., wherein the outermost surface of the seal layer has a coefficient of friction less than about 0.4; a metallized layer located on a side of the core layer opposite the seal layer; and a first tie layer intermediate the core layer and the seal layer or intermediate the core layer and the metallized layer.

In still another embodiment, the invention generally relates to metallized multi-layer films comprising a core layer; a seal layer located on a side of the core layer, the seal layer comprising a polyolefin polymer and a silicone gum, the silicone gum having a viscosity of at least two million centistokes at 25° C., wherein the outermost surface of the seal layer has a coefficient of friction less than about 0.4; a metallized layer located on a side of the core layer opposite the seal layer; a first tie layer intermediate the core layer and the seal layer; and a second tie layer intermediate the core layer and the metallized layer.

Another embodiment of the invention generally relates to a method of producing a metallized multi-layer film, the method comprising the steps of: forming a multi-layer film wherein the film comprises a core layer, a seal layer located on a side of the core layer, the seal layer comprising a polyolefin polymer and a silicone gum, the silicone gum having a viscosity of at least two million centistokes at 25° C., wherein the outermost surface of the seal layer has a coefficient of friction less than about 0.4, and a metallized layer located on a side of the core layer opposite the seal layer; treating the outermost surface of the metallized layer with at least one of plasma, corona, flame or polarized flame prior to metallization; and metallizing the outermost surface of the metallized layer with at least one vacuum deposited metal selected from the group consisting of aluminum, gold, silver, chromium, tin, copper, and combinations thereof.

The metallized multi-layer film may have a water vapor transmission rate less than 0.5 g/m²/24 hours, an oxygen transmission rate less than 100 cc/m²/24 hours, an optical density greater than 2.0 and a tensile modulus of at least 2200 N/mm².

The invention also encompasses finished packages, pouches, sealed bags and other articles embodying the film structures above.

### DETAILED DESCRIPTION OF THE INVENTION

Various specific embodiments, versions and examples of the invention will now be described, including definitions that are adopted herein for purposes of understanding the claimed invention. While the following detailed description gives specific preferred embodiments, those skilled in the art will appreciate that these embodiments are exemplary only, and that the invention can be practiced in other ways. For purposes of determining infringement, the scope of the invention will refer to the appended claims and elements or limitations that are equivalent to those that are recited. Any reference to the “invention” may refer to one or more, but not necessarily all, of the embodiments defined by the claims.

As used herein, “polymer” may be used to refer to homopolymers, copolymers, interpolymers, terpolymers, etc. Likewise, a “copolymer” may refer to a polymer comprising two monomers or to a polymer comprising three or more monomers.

As used herein, “isotactic” is defined as polymeric stereoregularity having at least 40% isotactic pentads of methyl groups derived from propylene according to analysis by ¹³C-NMR.

As used herein, “intermediate” is defined as the position of one layer of a multi-layer film wherein said layer lies between two other identified layers. In some embodiments, the intermediate layer may be in direct contact with either or both of the two identified layers. In other embodiments, additional layers may also be present between the intermediate layer and either or both of the two identified layers.

As used herein, “substantially free” is defined to mean that the referenced film layer is largely, but not necessarily wholly, absent a particular component. In some embodiments, small amounts of the component may be present within the referenced layer as a result of standard manufacturing methods or migration through the polymer layers over time.

As used herein, “coefficient of friction” and “COF” are defined to mean the kinetic film-to-film coefficient of friction as described herein and measured according to ASTM D-1894.

Films according to this invention comprise an arrangement of polymeric layers that contribute individually and collectively to improving metal adhesion on the outermost surface of one side of the multi-layer film, contributing to improved appearance and barrier properties, while maintaining an excellent coefficient of friction on the outermost surface of the opposite side of the multi-layer film to aid processability.

In the multi-layer films of this invention, silicone gum is incorporated into a seal layer to facilitate the advantages stated above.

In a preferred embodiment, this invention relates to a metallized multi-layer polymeric film having improved metal adhesion and excellent COF comprising a core layer, a seal layer located on a side of the core layer, the seal layer comprising a polyolefin polymer and a silicone gum, the silicone gum having a viscosity of at least two million centistokes at 25° C., wherein the outermost surface of the seal layer has a coefficient of friction less than about 0.4, and a metallized layer located on a side of the core layer opposite the seal layer.

### Core Layer

As is known to those skilled in the art, the core layer of a multi-layered film is most commonly the thickest layer and provides the foundation of the multi-layer structure. The core layer of the multi-layer film according to the present invention comprises a film-forming polyolefin, such as, for example, propylene homopolymer, isotactic polypropylene homopolymer (iPP), high density polyethylene (HDPE), high crystalline polypropylene (HCPP) or combinations thereof. In a preferred embodiment, the core layer is an iPP homopolymer. An example of a suitable iPP is ExxonMobil PP4712E1 (commercially available from ExxonMobil Chemical Company of Baytown, Tex.). Another suitable iPP is Total Polypropylene 3371 (commercially available from Total Petrochemicals of Houston, Tex.).

As is well known in the art, cavitating agents may also be present in the core layer. Generally, cavitating agents may be present in an amount ranging from about 2 wt % to about 30 wt %, preferably from about 5 wt % to about 15 wt %. Cavitating agents may include any suitable organic or inorganic particulate material that is incompatible with the polymer material(s) of the core layer so that, upon stretching of the film during orientation, voids form around some or all of the cavitating agent particles, thereby creating an opaque material. For example, the cavitating agent(s) may be any of those described in U.S. Pat. Nos. 4,377,616, 4,632,869 and 5,691,043, the entire disclosures of which are incorporated herein by reference. Specific examples of suitable cavitating agents are cyclo-olefin polymers and copolymers, polybutylene terephthalate (PBT), nylon, solid glass spheres, hollow glass spheres, metals beads or spheres, ceramic spheres, calcium carbonate, talc, chalk and combinations thereof. The average diameter of the cavitating particles typically may be from about 0.1 μm to 10 μm. Cavitation may also be introduced by beta-cavitation, which includes creating beta-form crystals of polypropylene and converting at least some of the beta-form crystals to alpha-form crystals upon stretching, thereby creating a small void near each alpha-crystal. Preferred beta-cavitated embodiments of the core layer may also comprise a beta-crystalline nucleating agent. Substantially any beta-crystalline nucleating agent (“beta nucleating agent” or “beta nucleator”) may be used.

The core layer may further comprise opacifying agents, pigments or colorants in an amount ranging from about 1 wt % to about 3 wt % based on the total weight of the core layer. Examples of suitable opacifying agents, pigments or colorants are iron oxide, carbon black, aluminum, titanium dioxide (TiO₂), calcium carbonate (CaCO₃), PBT, talc, beta nucleating agents, and combinations thereof.

The core layer of the present invention is substantially free from slip agents and antistatic agents, including silicone gum. The use of such agents in the core layer would adversely affect both metal adhesion and the barrier properties of the metallized multi-layer film.

The core layer preferably has a thickness in the range of from about 10 μm to 48 μm, more preferably from about 13 μm to 33 μm.

### Seal Layer

In some embodiments of this invention, the seal layer is contiguous to the core layer. In other embodiments, one or more other layers may be intermediate the seal layer and the core layer. The seal layer includes a polymer that is suitable for heat-sealing or bonding to itself when crimped between heated crimp-sealer jaws. In some preferred embodiments, the seal layer comprises at least one polymer selected from the group consisting of ethylene-propylene (EP) random copolymers, propylene-ethylene (PE) random copolymers, propylene-butylene (PB) random copolymers, ethylene-propylene-butylene (EPB) terpolymers, polypropylene plastomers, polyethylene plastomers, and combinations thereof. PB random copolymers suitable for use in this invention are Borealis TD210BF (commercially available from Borealis A/S of Denmark) and BP KS 399 (commercially available from British Petroleum of Great Britain). Suitable EPB terpolymers for use in this invention are Adsyl 5C39F and Adsyl 7384SCP (commercially available from Basell Polyolefins of The Netherlands) and Chisso 7701 and Chisso 7794 (commercially available from Japan Polypropylene Corporation of Japan).

The seal layer includes a silicone gum. Silicone gum serves to improve processability of the film by lowering the coefficient of friction of the outermost surface of the seal layer.

One silicone gum useful for inclusion in the seal layer of the present invention is a high-viscosity polydialkylsiloxane compound. An example of a structure of a silicone gum is HOMe₂SiO(Me₂SiO)ₙSiMe₂OH, in which Me is methyl and n is an integer having a value which can be as much as 1 million.

Silicone gums are not flowable at room temperature. Silicone gums may have the consistency of tough putty or hard deformable plastic. The viscosity of commercially available silicone gums may exceed 10⁶ centistokes, for example, the viscosity of silicone gum may be from about 1 to about 20 million centistokes, or higher.

In some embodiments of this invention, the silicone gum may have a viscosity at 25° C. greater than 2 million centistokes, preferably greater than 10 million centistokes, most preferably greater than 20 million centistokes.

The high molecular weight and high viscosity of silicone gum impede it from migrating throughout the film structure or from surface-to-surface transfer upon winding of the film. Thus, silicone gum displays a reduced transfer effect, which lends the multi-layer film improved converting properties. When properly blended and extruded with the polymer of the seal layer, the silicone gum is evenly distributed throughout the polymer of the seal layer.

The silicone gum can be in the form of a silicone polymer dispersed in polypropylene or polyethylene. Suitable silicone gums of this kind include the 50% masterbatch, “ultra-high molecular weight” products “MB50-001” and “MB50-002” from the Dow Corning Corporation, of Midland, Mich.

The silicone gum can be included in the seal layer of the metallized multi-layer film structure in an amount of from about 0.1 wt % to about 2 wt %, based on the entire weight of the seal layer. In the case where the silicone gum is added in masterbatch form, sufficient amounts of masterbatch can be used to ensure that the final level of silicone gum falls within the desired level of from about 0.1 wt % to about 2 wt %, based on the entire weight of the seal layer. For example, from about 0.2 wt % to about 4 wt % of Dow Corning's MB50-001 masterbatch can be added to the seal layer.

By employing sufficient amounts of silicone gum in the seal layer, a metallized multi-layer film structure is provided that exhibits excellent coefficient of friction in the outermost surface of the seal layer, thereby aiding machinability. Additionally, the non-migratory nature of the high molecular weight and high viscosity silicone gum facilitates improved wetting tension of the outermost surface of the metallizable layer (i.e., the metallized layer prior to metallization). The improved wetting tension allows for superior metal adhesion thus improving the appearance and barrier properties of the metallized multi-layer film

In a preferred embodiment of this invention, the outermost surface of the seal layer has a coefficient of friction less than about 0.4, more preferably less than 0.3.

The seal layer may contain antiblock additives used in amounts ranging from 1000 ppm to 2000 ppm based on the polymer composition of the layer. Antiblock additives include inorganic particulates such as silicone dioxide, e.g., a particulate antiblock sold by W.R. Grace under the trademark “SYLOBLOC 44”, calcium carbonate, magnesium silicate, aluminum silicate, calcium phosphate and e.g., Kaopolite.

Another useful particulate antiblock agent is referred to as a non-meltable, crosslinked silicone resin powder sold under the trademark “TOSPEARL” made by Toshiba Silicone Co., Ltd.; TOSPEARL is described in U.S. Pat. No. 4,769,418. Another useful antiblock additive is a spherical particle made from methyl methacrylate resin sold under the trademark “EPOSTAR” commercially available from Nippon Shokubai of Japan.

The seal layer preferably has a thickness in the range from about 0.5 μm to about 8.0 μm.

### Metallized Layer

The metallized layer is located on the opposite side of the core layer from the seal layer. In some embodiments of this invention, the metallized layer is contiguous to the core layer. In other embodiments, one or more other layers may be intermediate the core layer and the metallized layer. The metallized layer of the present invention preferably comprises at least one polymer selected from the group consisting of ethylene-propylene (EP) random copolymers, propylene-butylene (PB) random copolymers, butylene copolymers, ethylene-propylene-butylene (EPB) terpolymers, high density polyethylene (HDPE), ethylene vinyl alcohol (EVOH) copolymers and combinations thereof. Suitable EP random copolymers for use in this invention are BP KS407 (commercially available from British Petroleum of Great Britain) and Fina 8573 (commercially available from Total Petrochemicals USA of Houston, Tex.); PB random copolymers include Clyrell RC 1601 and Adsyl 3C30FHP (commercially available from Basell Polyolefins of The Netherlands); possible EPB terpolymers include Adsyl 3C30F (commercially available from Basell Polyolefins of The Netherlands). A suitable HDPE is HD6704.67 (commercially available from ExxonMobil Chemical Company of Baytown, Tex.). An example of a suitable EVOH is EVALEPG 156B (commercially available from Kuraray Company Ltd. of Japan).

The metallized layer of the present invention is substantially free from slip agents and antistatic agents, including silicone gum. The use of such agents in the metallized layer would adversely affect both metal adhesion and the barrier properties of the resulting film.

Before applying the metal to the metallized layer, the outer surface of the film may be treated as noted herein to increase its surface energy. This treatment can be accomplished by employing known techniques such as flame treatment, plasma treatment, polarized flame, corona discharge, film chlorination, e.g., exposure of the film surface to gaseous chlorine, treatment with oxidizing agents such as chromic acid, hot air or steam treatment, flame treatment and the like. Although any of these techniques is effectively employed to pre-treat the film surface, a frequently preferred method is corona discharge, an electronic treatment method that includes exposing the film surface to a high voltage corona discharge while passing the film between a pair of spaced electrodes. After treatment of the film surface, the metal is then applied thereto.

The outer surface of the metallized layer is preferably metallized using conventional methods, such as vacuum metallization by deposition of a metal layer such as aluminum, copper, silver, chromium or mixtures thereof. The metal coating is preferably applied to the metallized layer of the multi-layer film to an optical density of greater than 2.0. Optical density is a measure of the absorption of visual light and is determined by standard techniques.

Upon metallization, the metallized film exhibits excellent oxygen transmission rate (OTR) and water vapor transmission rate (WVTR) characteristics. For example, a metallized film according to the present invention may exhibit an OTR of less than 100 cc/m²/24 hours and a WVTR less than 0.5 g/m²/24 hours. These improved physical properties make the film ideally suited for packaging food products.

The metallized layer preferably has a thickness in the range from about 0.2 μm to about 2.0 μm, more preferably from about 0.5 μm to about 1.0 μm.

### Tie Layers

As is known to those skilled in the art, the tie layer of a multi-layer film is typically used to connect two other partially or fully incompatible layers of the multi-layer film structure, e.g., a core layer and a seal layer, and is positioned intermediate and in direct contact with these other layers.

In some embodiments of this invention, the film described herein may be a 4-layer metallized multi-layer film, including a core layer, a seal layer, and a metallized layer, all as described above, and a tie layer located either (a) intermediate the core layer and the seal layer or (b) intermediate the core layer and the metallized layer. In other embodiments, the multi-layer film described herein may be a 5-layer metallized multi-layer film, including a core layer, a seal layer, a metallized layer, a first tie layer located intermediate the core layer and the seal layer and a second tie layer located intermediate the core layer and the metallized layer. The tie layers of the present invention preferably comprise at least one polymer selected from the group consisting of polypropylene homopolymer, isotactic polypropylene homopolymer, high density polyethylene and combinations thereof.

In some embodiments, at least one of the first tie layer and second tie layer may include opacifying agents, pigments or colorants in an amount ranging from about 1 wt % to about 10 wt % based on the total weight of the tie layer. Examples of suitable opacifying agents, pigments or colorants are iron oxide, carbon black, aluminum, titanium dioxide (TiO₂), calcium carbonate (CaCO₃), polybutylene terephthalate (PBT), talc, beta nucleating agents, and combinations thereof.

The first tie layer and second tie layer of the present invention are substantially free from slip agents and antistatic agents, including silicone gum. The use of such agents in either tie layer would adversely affect both metal adhesion and the barrier properties of the metallized multi-layer film.

### Film Orientation

The embodiments of this invention include possible uniaxial or biaxial orientation of the multi-layer films. Orientation in the direction of extrusion is known as machine direction (MD) orientation. Orientation perpendicular to the direction of extrusion is known as transverse direction (TD) orientation. Orientation may be accomplished by stretching or pulling a film first in the MD followed by TD orientation. Blown films or cast films may also be oriented by a tenter-frame orientation subsequent to the film extrusion process, again in one or both directions. Orientation may be sequential or simultaneous, depending upon the desired film features. Preferred orientation ratios are commonly from between about three to about six times the extruded width in the machine direction and between about four to about ten times the extruded width in the transverse direction. Typical commercial orientation processes are BOPP tenter process, blown film and LISIM technology.

Typically, the films of the present invention are oriented prior to metallization. The resulting oriented film exhibits excellent tensile modulus characteristics. For example, an oriented film according to the present invention may exhibit a tensile modulus of at least 2200 N/mm² in the machine direction and preferably at least 3000 N/mm² in the transverse direction as determined according to ASTM D-882.

### INDUSTRIAL APPLICABILITY

Metallized, multi-layer films according to the present invention are useful as substantially stand-alone film webs or they may be coated and/or laminated to other film structures. Metallized, multi-layer films according to the present invention may be prepared by any suitable methods comprising the steps of co-extruding a multi-layer film according to the description and claims of this specification, orienting and preparing the film for intended use such as by coating, printing, slitting or other converting methods. Preferred methods comprising co-extruding, then casting and orienting the multi-layer film, followed by metallization, as discussed in this specification.

For some applications, it may be desirable to laminate the multi-layer films of this invention to other polymeric film or paper products for purposes such as package decor including printing. These activities are typically performed by the ultimate end-users or film converters who process films for supply to the ultimate end-users.

In one embodiment, a method of preparing a metallized, multi-layer film according to the present invention comprises at least the steps of forming a multi-layer film, wherein the film comprises:
a core layer;
a seal layer located on a side of the core layer, the seal layer comprising a polyolefin polymer and a silicone gum, the silicone gum having a viscosity of at least 2 million centistokes at 25° C., wherein the outermost surface of the seal layer has a coefficient of friction less than about 0.4; and
a metallized layer located on a side of the core layer opposite the seal layer.

The method may further comprise the step of treating the outermost surface of the metallized layer with at least one of flame, plasma, corona discharge or polarized flame prior to metallization.

The method may also comprise metallizing the outermost surface of the metallized layer with at least one vacuum deposited metal selected from the group consisting of aluminum, gold, silver, chromium, tin, copper and combinations thereof.

Additionally, the method may comprise enclosing a product or article within at least a portion of the metallized multi-layer film.

Still further, the method may comprise forming a tie layer located intermediate the core layer and seal layer and/or a tie layer located intermediate the core layer and the metallized layer.

The prepared metallized multi-layer film may be used as a flexible packaging film to package an article or good, such as a food item or other product. In some applications, the film may be formed into a pouch type of package, such as may be useful for packaging a beverage, liquid, granular, or dry-powder product.

### EXPERIMENTAL

The metallized multi-layer film of the present invention will be further described with reference to the following non-limiting examples.

### Testing Methods

Coefficient of friction is measured according to ASTM D-1894.

Viscosity is measured according to ASTM D-445.

Water vapor transmission rate is measured according to ASTM F-1249.

Oxygen transmission rate is measured according to ASTM D-3985.

Optical density is a measure of the absorption of visual light, and is determined by standard techniques (ANSI/NAPM IT2.19). To calculate optical density, a commercial densitometer may be used, such as a Macbeth model TD 932, Tobias Densitometer model TDX or Macbeth model TD903. The densitometer is set to zero with no film specimen. A film specimen is placed over the aperture plate of the densitometer with the test surface facing upwards. The probe arm is pressed down and the resulting optical density value is recorded.

Tensile modulus is measured according to ASTM D-882.

Wetting tension is measured according to ASTM D-2578.

### EXAMPLES

Two sample rolls of clear film were produced on a pilot line with silicone gum in the sealant layer and were metallized 5 months later. The films had a three layer structure, as follow:

| SAMPLE A | Polymer | Thickness (μm) |
|---|---|---|
| Metallized layer | Fina 8573 - EP copolymer | 0.75 |
| Core layer | Fina 3371 - isotactic polypropylene | 16 |
| Seal layer | Chisso 7701 - terpolymer and 0.5% | 0.75 |
| | Dow Corning 50-001 masterbatch | |

| SAMPLE B | Polymer | Thickness (μm) |
|---|---|---|
| Metallized layer | Fina 8573 - EP copolymer | 0.75 |
| Core layer | Fina 3371 - isotactic polypropylene | 16 |
| Seal layer | Chisso 7701 - terpolymer and 1.0% | 0.75 |
| | Dow Corning 50-001 masterbatch | |

As can be seen from the above, the film examples were identical, with the sole exception of the amount of Dow Corning 50-001 included in the seal layer. Dow Corning 50-001 is a masterbatch containing 50% ultra high molecular weight silicone (polydimethylsiloxane) in polypropylene.

After 5 months, the wetting tension of the outermost surface of the metallized layer of each sample was measured prior to addition of the metal and reported as follows:

TABLE I

| | Wetting Tension | |
|---|---|---|
| | Outermost surface of Metallized layer | |
| Sample A | 42 | dynes/cm |
| Sample B | 38–39 | dynes/cm |

It would not be possible to obtain this measurement for the film if it had been produced with silicone oil in the seal layer rather than silicone gum. Silicone oil would transfer from the surface of the seal layer to the surface of the metallized layer upon contact between the layers when the film is wound on a reel, rendering the wetting tension measure unattainable.

Additionally, the COF of the outermost surface of the seal layers was tested and reported as follows:

TABLE II

| | Coefficient of Friction |
|---|---|
| | Outermost surface of Seal layer |
| Sample A | 0.27–0.32 |
| Sample B | 0.20–0.21 |

By way of reference, the coefficient of friction of a film not formulated with additives would range from approximately 0.70 to 1.0. A film formulated with an organic anti-block agent would result in a coefficient of friction from approximately 0.4 to 0.5 and a film formulated with either a slip migrating amine or silicone oil would result in a coefficient of friction ranging from approximately 0.2 to 0.3.

Next, both film samples were metallized in a bell jar laboratory metallizer and yielded the following results:

TABLE III

| | Metal Adhesion | | Oxygen | Water Vapor |
|---|---|---|---|---|
| | (no pick off | Optical | Transmission | Transmission |
| | after tape test) | Density | Rate | Rate |
| Sample A | Very good | 2.6 | 82 cc/m²/24 hr | 0.46 g/m²/24 hr |
| Sample B | Very good | 2.7 | 53 cc/m²/24 hr | 0.46 g/m²/24 hr |

Films containing a migratory slip additive in the core layer or silicone oil in the sealant layer demonstrate poor metal adhesion and inconsistent metallized barrier properties. Absent these additives, a film would exhibit good metal adhesion and barrier properties, but would lack the slip properties (i.e., high COF of the outermost surface of the seal layer) necessary for processability.

As we have demonstrated above, the structures of this invention have dramatically improved metal adhesion and consistent barrier properties while exhibiting excellent slip characteristics required for machinability.

The present invention is described herein with reference to embodiments of multi-layer films, however, various other film structures are contemplated. Those skilled in the art will appreciate that numerous modifications to these embodiments may be made without departing from the scope of our invention. For example, while certain film layers are exemplified as being comprised of specific polymer blends and additives, along with a certain arrangement of layers within the film, other compositions and arrangements are also contemplated. Additionally, while packaging is discussed among the uses for embodiments of our inventive films, other uses, such as labeling and printing, are also contemplated.

To the extent that this description is specific, it is solely for the purpose of illustrating certain embodiments of the invention and should not be taken as limiting the present inventive concepts to these specific embodiments. Therefore, the spirit and scope of the appended claims should not be limited to the description of the embodiments contained herein.

What is claimed is:

1. A metallized multi-layer film, comprising:
(a) a core layer;
(b) a seal layer located on a side of said core layer, said seal layer comprising a polyolefin polymer and a silicone gum, the silicone gum having a viscosity of at least 2 million centistokes at 25° C., wherein the outermost surface of said seal layer has a coefficient of friction less than about 0.4; and
(c) a metallized layer located on a side of said core layer opposite said seal layer.

2. The metallized multi-layer film of claim 1, wherein said core layer comprises at least one polymer selected from the group consisting of polypropylene homopolymer, isotactic polypropylene homopolymer, high density polyethylene, high crystalline polypropylene and combinations thereof.

3. The metallized multi-layer film of claim 2, wherein said core layer further comprises a cavitating agent selected from the group consisting of cyclo-olefin polymers and copolymers, polybutylene terephthalate, nylon, solid glass spheres, hollow glass spheres, metal beads or spheres, ceramic spheres, calcium carbonate, talc, chalk and combinations thereof.

4. The metallized multi-layer film of claim 1, wherein said core layer has a thickness in the range of from about 10 microns to about 48 microns.

5. The metallized multi-layer film of claim 1, wherein said core layer has a thickness in the range of from about 13 microns to about 33 microns.

6. The metallized multi-layer film of claim 1, wherein said polyolefin polymer of said seal layer is selected from the group consisting of ethylene-propylene random copolymer, propylene-ethylene random copolymer, propylene-butylene random copolymer, ethylene-propylene-butylene terpolymers, polypropylene plastomers, polyethylene plastomers, and combinations thereof.

7. The multi-layer film of claim 1, wherein said silicone gum has a viscosity greater than 10 million centistokes at 25° C.

8. The multi-layer film of claim 1, wherein said silicone gum has a viscosity greater than 20 million centistokes at 25° C.

9. The metallized multi-layer film of claim 1, wherein said seal layer comprises from about 0.1 wt % to about 2.0 wt % silicone gum.

10. The metallized multi-layer film of claim 1, wherein said seal layer has a thickness in the range of from about 0.5 microns to about 8.0 microns.

11. The metallized multi-layer film of claim 1, wherein said metallized layer comprises at least one polymer selected from the group consisting of ethylene-propylene random copolymer, butylene copolymer, propylene-butylene random copolymer, an ethylene-propylene-butylene terpolymer, high density polyethylene, ethylene vinyl alcohol copolymer, and combinations thereof.

12. The metallized multi-layer film of claim 1, wherein said metallized layer has a thickness in the range of from about 0.2 microns to about 2.0 microns.

13. The metallized multi-layer film of claim 1, wherein said metallized layer has a thickness in the range of from about 0.5 microns to about 1.0 microns.

14. The metallized multi-layer film of claim 1, wherein said metallized layer is treated on the outermost surface with at least one of flame, plasma, corona discharge or polarized flame prior to metallization.

15. The metallized multi-layer film of claim 14, wherein the outermost surface of the metallized layer is vacuum metallized with at least one metal selected from the group consisting of aluminum, gold, silver, chromium, tin, copper and combinations thereof.

16. The metallized multi-layer film of claim 1, wherein said film has a water vapor transmission rate less than 0.5 g/m²/24 hours.

17. The metallized multi-layer film of claim 1, wherein said film has an oxygen transmission rate less than 100 cc/m²/24 hours.

18. The metallized multi-layer film of claim 1, wherein said film has an optical density greater than 2.0.

19. The metallized multi-layer film of claim 1, wherein said film has a tensile modulus of at least 2200 N/mm².

20. The metallized multi-layer film of claim 1, further comprising at least one of (a) a first tie layer located intermediate said core layer and said seal layer, and (b) a second tie layer located intermediate said core layer and said metallized layer.

21. The metallized multi-layer film of claim 20, wherein at least one of said first tie layer and said second tie layer comprises at least one polymer selected from the group consisting of polypropylene homopolymer, isotactic polypropylene homopolymer, high density polyethylene and combinations thereof.

22. The metallized multi-layer film of claim 20, wherein at least one of said first tie layer and said second tie layer comprise at least one opacifying agent selected from the group consisting of iron oxide, carbon black, aluminum, titanium dioxide, calcium carbonate, polybutylene terephthalate, talc, beta nucleating agents and combinations thereof.

23. A metallized multi-layer film comprising:
(a) a core layer;
(b) a seal layer located on a side of said core layer, said seal layer comprising a polyolefin polymer and a silicone gum, the silicone gum having a viscosity of at least 2 million centistokes at 25° C., wherein said outermost surface of said seal layer has a coefficient of friction less than about 0.4;
(c) a metallized layer located on a side of said core layer opposite said seal layer; and
(d) a first tie layer intermediate to said core layer and said seal layer.

24. A metallized multi-layer film comprising:
(a) a core layer;
(b) a seal layer located on a side of said core layer, said seal layer comprising a polyolefin polymer and a silicone gum, the silicone gum having a viscosity of at least 2 million centistokes at 25° C., wherein said outermost surface of said seal layer has a coefficient of friction less than about 0.4;
(c) a metallized layer located on a side of said core layer opposite said seal layer;
(d) a first tie layer intermediate to said core layer and said seal layer; and
(e) a second tie layer intermediate to said core layer and said metallized layer.

25. A method for producing a metallized multi-layer film comprising the steps of:
(a) forming a multi-layer film, wherein said film comprises,
(i) a core layer;
(ii) a seal layer located on a side of said core layer, said seal layer comprising a polyolefin polymer and a silicone gum, the silicone gum having a viscosity of at least 2 million centistokes at 25° C., wherein said outermost surface of said seal layer has a coefficient of friction less than about 0.4; and
(iii) a metallized layer located on a side of said core layer opposite said seal layer,
(b) treating the outermost surface of said metallized layer with at least one of flame, plasma, corona discharge or polarized flame prior to metallization, and
(c) metallizing the outermost surface of said metallized layer with at least one vacuum deposited metal selected from the group consisting of aluminum, gold, silver, chromium, tin, copper and combinations thereof.

26. The method of claim 25, wherein said silicone gum has a viscosity greater than 10 million centistokes at 25° C.

27. The method of claim 25, wherein said silicone gum has a viscosity greater than 20 million centistokes at 25° C.

28. The method of claim 25, wherein said seal layer comprises 0.1 wt % to 2.0 wt % silicone gum.

29. The method of claim 25, wherein said metallized multi-layer film has a water vapor transmission rate less than about 0.5 g/m²/24 hours.

30. The method of claim 25, wherein said metallized multi-layer film has an oxygen transmission rate less than about 100 cc/m²/24 hours.

31. The method of claim 25, wherein said metallized multi-layer film has an optical density greater than about 2.0.

32. A metallized multi-layer film produced according to the method of claim 25.

33. A package comprising a metallized multi-layer film comprising:
(a) a core layer;
(b) a seal layer located on a side of said core layer, said seal layer comprising a polyolefin polymer and a silicone gum, the silicone gum having a viscosity of at least 2 million centistokes at 25° C., wherein said outermost surface of said seal layer has a coefficient of friction less than about 0.4; and
(c) a metallized layer located on a side of said core layer opposite said seal layer,
said metallized multi-layer film being formed into a package adapted to contain a product.
